(19) United States
(12) Patent Application Publication
(10) Pub. No.: US 2026/0271304 A1
(43) Pub. Date: Sep. 10, 2026

(54) STORAGE DEVICE

(71) Applicant: Kioxia Corporation, Tokyo (JP)

(72) Inventor: Eiji KITAGAWA, Seoul (KR)

(73) Assignee: Kioxia Corporation, Tokyo (JP)

(21) Appl. No.: 19/237,058

(22) Filed: Jun. 13, 2025

(30) Foreign Application Priority Data
Mar. 5, 2025 (JP) 2025-034869

(51) Int. Cl. H10B 61/00; G11C 5/06; G11C 5/08; H10N 50/10; H10N 50/85

(52) U.S. Cl. CPC H10B 61/10; G11C 5/063; G11C 5/08; H10N 50/10; H10N 50/85

(57) ABSTRACT

According to embodiments, a storage device includes a first interconnect extending in a first direction, a switching element provided on the first interconnect and containing silicon (Si), oxygen (O), arsenic (As), and at least one element selected from the group consisting of thallium (Tl) and boron (B), a variable resistance element provided on the switching element, and a second interconnect extending in a second direction intersecting the first direction and provided on the variable resistance element.

### CROSS-REFERENCE TO RELATED APPLICATIONS

This application is based upon and claims the benefit of priority from Japanese Patent Application No. 2025-034869, filed Mar. 5, 2025, the entire contents of which are incorporated herein by reference.

### FIELD

Embodiments described herein relate generally to a storage device.

### BACKGROUND

A storage device using a variable resistance element as a memory element is known. For example, a magnetoresistive random access memory (MRAM) using a magnetoresistive effect element as a variable resistance element is known.

### BRIEF DESCRIPTION OF THE DRAWINGS

FIG. 1 is a block diagram showing an example of an overall configuration of a storage device according to a first embodiment.

FIG. 2 is a circuit diagram showing an example of a circuit configuration of a memory cell array included in the storage device according to the first embodiment.

FIG. 3 is a perspective view showing an example of a structure of the memory cell array included in the storage device according to the first embodiment.

FIG. 4 is a cross-sectional view showing an example of a configuration of a variable resistance element included in the storage device according to the first embodiment.

FIG. 5 is a cross-sectional view showing an example of a configuration of a selector included in the storage device according to the first embodiment.

FIG. 6 is a view showing (a) a conduction path of a selector SE with relatively large cluster sizes in a comparative embodiment and (b) a conduction path of a selector SE with relatively small cluster sizes in the embodiment.

FIG. 7 is a cross-sectional view showing an example of a configuration of a selector included in a storage device according to a second embodiment.

FIG. 8 is a cross-sectional view showing an example of a configuration of a selector included in a storage device according to a third embodiment.

FIG. 9 is a cross-sectional view showing an example of a configuration of a selector included in a storage device according to a fourth embodiment.

FIG. 10 is a view showing a cross-sectional view and a plan view of a selector included in the storage device according to a fifth embodiment.

### DETAILED DESCRIPTION

In general, according to one embodiment, a storage device includes a first interconnect extending in a first direction, a switching element provided on the first interconnect and containing silicon (Si), oxygen (O), arsenic (As), and at least one element selected from the group consisting of thallium (Tl) and boron (B), a variable resistance element provided on the switching element, and a second interconnect extending in a second direction intersecting the first direction and provided on the variable resistance element.

Embodiments will be described below with reference to the accompanying drawings. In the following description, the same reference numerals denote constituent elements having the same functions and configurations. If a plurality of constituent elements having the same reference numerals are discriminated from each other, suffixes are attached to the same reference numerals. If there is no need to discriminate such constituent elements, only the same reference numerals are attached to the constituent elements without any suffixes. In this case, the suffixes include, in addition to subscripts and superscripts, for example, lowercase alphabets and indices indicating arrays which are attached to the ends of reference numerals.

### 1. First Embodiment

A storage device according to the first embodiment will be described first. The first embodiment will exemplify, as a storage device, a magnetic storage device of a perpendicular magnetization system using, as a variable resistance element, an element (to be also referred to as an “MTJ element” hereinafter) having a magnetoresistive effect based on a magnetic tunnel junction (MTJ).

In the following description, an MTJ element is applied as a variable resistance element. For the sake of descriptive convenience, the embodiments will be described below with a variable resistance element being written as a magnetoresistive effect element MTJ. Note that a variable resistance element is not limited to the magnetoresistive effect element MTJ. The present invention can also be applied to a variable resistance element having the property of storing different pieces of information according to resistive states.

### 1.1 Overall Configuration of Magnetic Storage Device

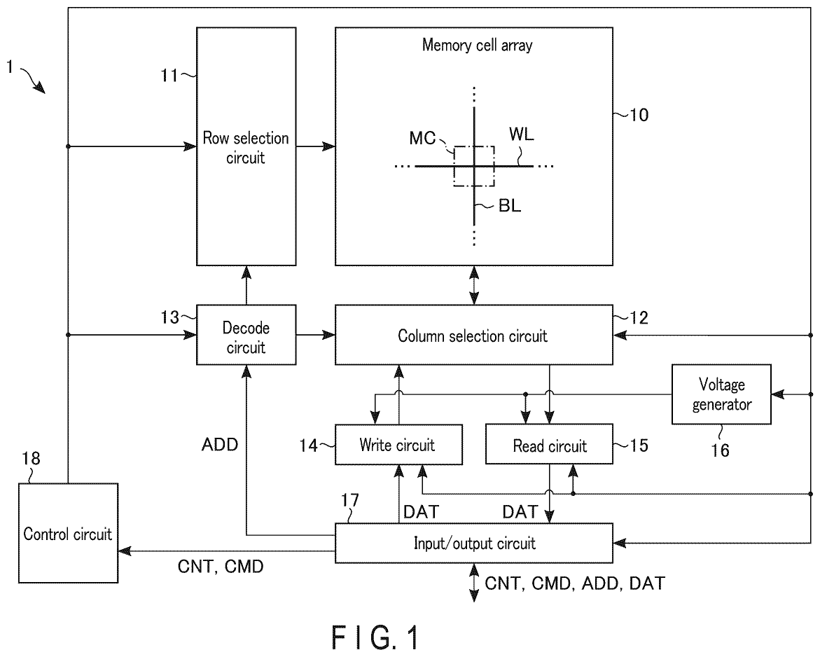

An example of an overall configuration of a storage device 1 will be described first with reference to FIG. 1. FIG. 1 is a block diagram showing an example of an overall configuration of the storage device 1. In the example shown in FIG. 1, some of the couplings between the respective constituent elements are indicated by arrow lines. However, the couplings between the respective constituent elements are not limited to this.

As shown in FIG. 1, the storage device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC. Each memory cell MC is associated with a set of a row and a column. More specifically, the memory cells MC on the same row are coupled to the same word line WL, and the memory cells MC on the same column are coupled to the same bit line BL.

The row selection circuit 11 is a circuit that selects an interconnect (the word line WL) in the row direction. The row selection circuit 11 is coupled to the memory cell array 10 via the word line WL. The row selection circuit 11 is also coupled to the decode circuit 13 and the control circuit 18. The row selection circuit 11 receives the decoding result of an address ADD (row address) from the decode circuit 13. The row selection circuit 11 sets the corresponding word line WL in a selected state based on the decoding result of the address ADD.

The column selection circuit 12 is a circuit that selects an interconnect (the bit line BL) in the column direction. The column selection circuit 12 is coupled to the memory cell array 10 via the bit line BL. The column selection circuit 12 is also coupled to the decode circuit 13, the write circuit 14, the read circuit 15, and the control circuit 18. The column selection circuit 12 receives the decoding result of the address ADD (column address) from the decode circuit 13. The column selection circuit 12 sets the corresponding bit line BL in a selected state based on the decoding result of the address ADD.

The decode circuit 13 is a circuit that decodes the address ADD received from the input/output circuit 17. The decode circuit 13 is coupled to the row selection circuit 11, the column selection circuit 12, the input/output circuit 17, and the control circuit 18. The address ADD includes a column address and a row address. The decode circuit 13 transmits the decoding result of the address ADD to the row selection circuit 11 and the column selection circuit 12.

The write circuit 14 is a circuit that writes data DAT in the memory cell MC. The write circuit 14 is coupled to the column selection circuit 12, the voltage generator 16, the input/output circuit 17, and the control circuit 18. The write circuit 14 receives the data DAT from the input/output circuit 17. The write circuit 14 supplies a write current (voltage) based on the data DAT to the memory cell MC via the column selection circuit 12. The write circuit 14 includes, for example, a write driver (not shown).

The read circuit 15 is a circuit that reads the data DAT from the memory cell MC. The read circuit 15 is coupled to the column selection circuit 12, the voltage generator 16, the input/output circuit 17, and the control circuit 18. The read circuit 15 reads the data DAT from the memory cell MC via the column selection circuit 12. The read circuit 15 transmits the read data DAT to the input/output circuit 17. The read circuit 15 includes, for example, a sense amplifier (not shown).

The voltage generator 16 is a circuit that generates voltages used for various types of operations in the storage device 1 by using the power supply voltages provided from outside (not shown) of the storage device 1. The voltage generator 16 is coupled to the write circuit 14, the read circuit 15, and the control circuit 18. For example, the voltage generator 16 generates a voltage (current) used for a write operation and supplies the voltage to the write circuit 14. In addition, for example, the voltage generator 16 generates a voltage (current) used for a read operation and supplies the voltage to the read circuit 15.

The input/output circuit 17 is a circuit that inputs and outputs a control signal CNT, a command CMD, the address ADD, the data DAT, and the like from and to outside of the storage device 1. The input/output circuit 17 is coupled to the decode circuit 13, the write circuit 14, the read circuit 15, and the control circuit 18. The input/output circuit 17 transmits the address ADD received from outside of the storage device 1 to the decode circuit 13. The input/output circuit 17 transmits the command CMD and the control signal CNT received from outside of the storage device 1 to the control circuit 18. The input/output circuit 17 transmits and receives various types of control signals CNT between outside of the storage device 1 and the control circuit 18. The input/output circuit 17 transmits the data DAT received from outside of the storage device 1 to the write circuit 14. The input/output circuit 17 transmits the data DAT received from the read circuit 15 to outside of the storage device 1.

The control circuit 18 controls the operations of the row selection circuit 11, the column selection circuit 12, the decode circuit 13, the write circuit 14, the read circuit 15, the voltage generator 16, and the input/output circuit 17 in the storage device 1 based on the control signal CNT and the command CMD. The control circuit 18 also controls a write operation and a read operation.

### 1.2 Circuit Configuration of Memory Cell Array

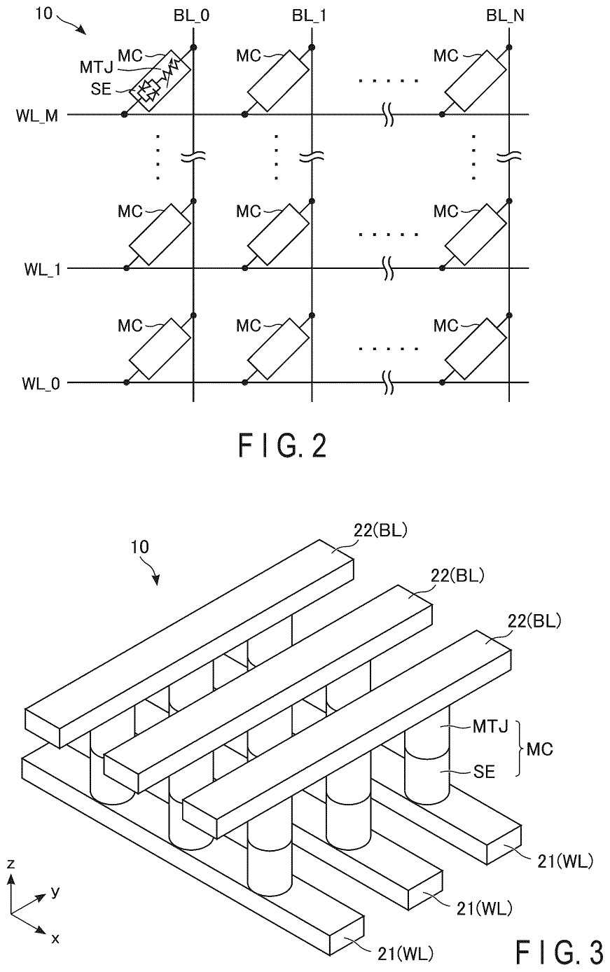

An example of a circuit configuration of the memory cell array 10 will be described next with reference to FIG. 2. FIG. 2 is a circuit diagram showing an example of a circuit configuration of the memory cell array 10 of the storage device 1.

As shown in FIG. 2, the memory cell array 10 is internally provided with M+1 word lines WL (WL_0, WL_1, . . . , and WL_M) and N+1 bit lines BL (BL_0, BL_1, . . . , BL_N). M and N are respectively positive integers.

Each memory cell MC includes the magnetoresistive effect element MTJ and a selector SE. The magnetoresistive effect element MTJ and the selector SE are coupled in series between the associated bit line BL and the associated word line WL. For example, one end of the magnetoresistive effect element MTJ is coupled to the bit line BL. The other end of the magnetoresistive effect element MTJ is coupled to one end of the selector SE. The other end of the selector SE is coupled to the word line WL. Note that the coupling relationship between the magnetoresistive effect element MTJ and the selector SE between the bit line BL and the word line WL may be reversed.

The magnetoresistive effect element MTJ is a variable resistance element corresponding to an MTJ element. The magnetoresistive effect element MTJ can store data in a nonvolatile manner based on the resistance value. For example, the memory cell MC including the magnetoresistive effect element MTJ in a high resistance state stores “1” data. The memory cell MC including the magnetoresistive effect element MTJ in a low resistance state stores “0” data. The assignment of data associated with the resistance value of the magnetoresistive effect element MTJ may be implemented according to other settings. The resistance state of the magnetoresistive effect element MTJ can change according to a current flowing through the magnetoresistive effect element MTJ.

The selector SE (to be also referred to as the “switching element”) functions as a switch that controls the supply of a current to the magnetoresistive effect element MTJ in the write operation and the read operation with respect to the magnetoresistive effect element MTJ. More specifically, for example, the selector SE in the memory cell MC cuts off (turns off) a current as an insulator having a high resistance value if the voltage applied to the memory cell MC is less than a threshold voltage set in advance. On the other hand, the selector SE causes a current to flow (turns on) as a conductor having a low resistance value if the voltage applied to the memory cell MC is equal to or more than the threshold voltage. That is, the selector SE has the function of switching between causing a current to flow and cutting off the current in accordance with the magnitude of the voltage applied to the memory cell MC regardless of the flowing direction of the current.

The selector SE may be, for example, a two-terminal switching element. If the voltage applied between the two terminals is less than the threshold voltage, the selector SE is in a high-resistance state or non-conductive state in which almost no current flows. If the voltage applied between the two terminals is equal to or more than the threshold voltage, the selector SE is in a low-resistance state, that is, in an electrically conductive state. The selector SE can have this function regardless of the polarity of the voltage.

### 1.3 Structure of Memory Cell Array

An example of a structure of a memory cell array will be described next with reference to FIG. 3. FIG. 3 is a perspective view showing an example of a structure of the memory cell array 10 of the storage device 1.

In the following description, an XYZ orthogonal coordinate system is used. The X direction corresponds to the extending direction of the word line WL. The Y direction intersects the X direction and corresponds to the extending direction of the bit line BL. The Z direction intersects the X direction and the Y direction.

As shown in FIG. 3, the memory cell array 10 includes a plurality of interconnect layers 21 and a plurality of interconnect layers 22.

The interconnect layer 21 has a portion extending in the X direction. The plurality of interconnect layers 21 are arranged side by side in the Y direction and separated from each other. Each interconnect layer 21 functions as the word line WL.

The interconnect layer 22 has a portion extending in the Y direction. The plurality of interconnect layers 22 are provided above the plurality of interconnect layers 21 in the Z direction. The plurality of interconnect layers 22 are arranged side by side in the X direction and separated from each other. Each interconnect layer 22 functions as the bit line BL.

In top view from the Z direction, one memory cell MC is provided at each of the intersections between the plurality of interconnect layers 21 and the plurality of interconnect layers 22. In other words, each memory cell MC is provided in a columnar shape between the associated bit line BL and the associated word line WL. In this case, the selector SE is provided on the interconnect layer 21. The magnetoresistive effect element MTJ is provided on the selector SE. The interconnect layer 22 is provided on the magnetoresistive effect element MTJ.

In the case shown in FIG. 3, the magnetoresistive effect element MTJ is provided on the selector SE. However, the selector SE may be provided on the magnetoresistive effect element MTJ. In the case shown in FIG. 3, the bit line BL is provided above the word line WL. However, the word line WL may be provided above the bit line BL. Alternatively, the two or more memory cells MC may be stacked through the bit line BL or the word line WL in the Z direction.

### 1.4 Configuration of Magnetoresistive effect Element

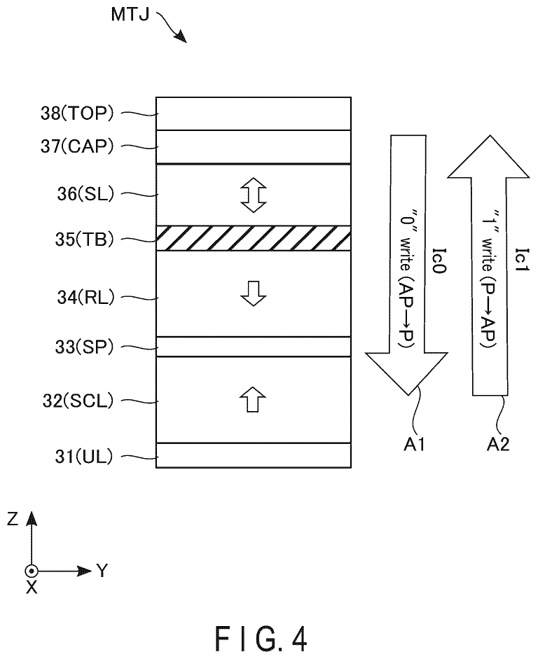

An example of a configuration of the magnetoresistive effect element MTJ will be described next with reference to FIG. 4. FIG. 4 is a cross-sectional view showing an example of a configuration of the magnetoresistive effect element MTJ.

As shown in FIG. 4, for example, the magnetoresistive effect element MTJ includes a nonmagnet 31, a ferromagnet 32, a nonmagnet 33, a ferromagnet 34, a nonmagnet 35, a ferromagnet 36, a nonmagnet 37, and a nonmagnet 38. The nonmagnet 31 functions as an under layer UL. The ferromagnet 32 functions as a shift cancelling layer SCL. The nonmagnet 33 functions as a spacer layer SP. The ferromagnet 34 functions as a reference layer RL. The nonmagnet 35 functions as a tunnel barrier layer TB. The ferromagnet 36 functions as a storage layer SL. The nonmagnet 37 functions as a cap layer CAP. The nonmagnet 38 functions as a top layer TOP.

The magnetoresistive effect element MTJ has a plurality of films stacked on each other from the word line WL (interconnect layer 21) side to the bit line BL (interconnect layer 22) side in the order of the nonmagnet 31, the ferromagnet 32, the nonmagnet 33, the ferromagnet 34, the nonmagnet 35, the ferromagnet 36, the nonmagnet 37, and the nonmagnet 38. Note that the plurality of films may be stacked on each other from the word line WL (interconnect layer 21) side to the bit line BL (interconnect layer 22) side in the order of the nonmagnet 38, the nonmagnet 37, the ferromagnet 36, the nonmagnet 35, the ferromagnet 34, the nonmagnet 33, the ferromagnet 32, and the nonmagnet 31.

The magnetoresistive effect element MTJ functions as, for example, a perpendicular magnetization type magnetoresistive effect element constituted by magnets whose magnetization directions are oriented in the perpendicular direction (the Z direction in the case shown in FIG. 4) with respect to the film surfaces. Note that the magnetoresistive effect element MTJ may further include layers (not shown) between the respective layers 31 to 38 described above.

The nonmagnet 31 is a nonmagnetic conductor and has a function as an electrode that improves the electrical coupling characteristics with the selector SE. The nonmagnet 31 may be a multilayer body constituted by a plurality of layers. For example, the nonmagnet 31 includes a high-melting-point metal. The high-melting-point metal is, for example, a material having a higher melting point than iron (Fe) and cobalt (Co) and includes at least one element selected from the group consisting of zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The ferromagnet 32 has ferromagnetism and an easy magnetization direction in a direction perpendicular to the film surface. The magnetization direction of the ferromagnet 32 is fixed and is oriented in the opposite direction relative to the ferromagnet 34 in the case shown in FIG. 4. Note that “the magnetization direction is fixed” means that the magnetization direction is not changed by a current (spin torque) large enough to rotate the magnetization direction of the ferromagnet 36 (the storage layer SL). The ferromagnet 32 contains, for example, cobalt (Co). Note that the ferromagnet 32 can include at least one a multilayer film selected from the group consisting of a multilayer film (Co/Pt multilayer film) constituted by cobalt (Co) and platinum (Pt), a multilayer film (Co/Ni multilayer film) constituted by cobalt (Co) and nickel (Ni), and a multilayer film (Co/Pd multilayer film) constituted by cobalt (Co) and palladium (Pd).

The nonmagnet 33 is provided between the ferromagnet 32 (the shift cancelling layer SCL) and the ferromagnet 34 (the reference layer RL). The nonmagnet 33 is a nonmagnetic conductor and contains at least one element selected from the group consisting of, for example, ruthenium (Ru), osmium (Os), iridium (Ir), vanadium (V), and chromium (Cr).

The ferromagnet 34 has ferromagnetism and an easy magnetization direction in a direction perpendicular to the film surface. The magnetization direction of the ferromagnet 34 is fixed and is oriented in the opposite direction relative to the ferromagnet 32 in the case shown in FIG. 4. The ferromagnet 34 contains at least one element selected from the group consisting of, for example, iron (Fe), cobalt (Co), and nickel (Ni). The ferromagnet 34 may further contain boron (B). More specifically, for example, the ferromagnet 34 contains iron-cobalt-boron (FeCoB) or iron-boron (FeB) and can have a body-centered crystal structure.

Although not shown in FIG. 4, the ferromagnet 34 may be a multilayer body constituted by a plurality of layers. More specifically, for example, the multilayer body forming the ferromagnet 34 may have a structure having a layer containing the above iron-cobalt-boron (FeCoB) or iron-boron (FeB) as an interface layer with the nonmagnet 35 and further having a ferromagnet between the interface layer and the nonmagnet 33 through a nonmagnetic conductor. The nonmagnetic conductor in the multilayer body forming the ferromagnet 34 can contain at least one metal selected from the group consisting of, for example, tantalum (Ta), hafnium (Hf), tungsten (W), zirconium (Zr), molybdenum (Mo), niobium (Nb), and titanium (Ti). The ferromagnet further included in the multilayer body forming the ferromagnet 34 can include at least one multilayer film selected from the group consisting of, for example, a multilayer film (Co/Pt multilayer film) constituted by cobalt (Co) and platinum (Pt), a multilayer film (Co/Ni multilayer film) constituted by cobalt (Co) and nickel (Ni), and a multilayer film (Co/Pd multilayer film) constituted by cobalt (Co) and palladium (Pd).

The ferromagnets 32 and 34 are anti-ferromagnetically coupled to each other through the nonmagnet 33. That is, the ferromagnets 32 and 34 are coupled so as to have magnetization directions antiparallel to each other. Accordingly, in the case shown in FIG. 4, the magnetization directions of the ferromagnets 32 and 34 are oriented in directions opposite to each other. Such coupled structure of the ferromagnet 32, the nonmagnet 33, and the ferromagnet 34 is called a synthetic anti-ferromagnetic (SAF) structure. With this structure, the ferromagnet 32 can cancel out the influence of a stray field of the ferromagnet 34 on the magnetization direction of the ferromagnet 36. This suppresses to occur asymmetry in the easiness of magnetization reversal of the ferromagnet 36 due to the stray field of the ferromagnet 34 (that is, the easiness of the reversal of the magnetization direction of the ferromagnet 36 differs when reversal occurs from one side to the other side and when reversal occurs in the opposite direction).

The nonmagnet 35 is a nonmagnetic insulator and contains, for example, magnesium oxide (MgO). The nonmagnet 35 has, for example, an NaCl crystal structure in which the film surface is oriented in a (001) plane and functions as a seed material serving as a nucleus for growing a crystalline film from an interface with the ferromagnet 36 in the crystallization processing of the ferromagnet 36. The nonmagnet 35 is provided between the ferromagnet 34 and the ferromagnet 36 and forms a magnetic tunnel junction together with these two ferromagnets.

The ferromagnet 36 has ferromagnetism and an easy magnetization axis direction in a direction perpendicular to the film surface. In other words, the ferromagnet 36 has a magnetization direction extending to one of the directions on the bit line BL side and the word line WL side along the Z direction. The ferromagnet 36 contains at least one element selected from the group consisting of iron (Fe), cobalt (Co), and nickel (Ni). The ferromagnet 36 further contains boron (B). More specifically, for example, the ferromagnet 36 contains iron-cobalt-boron (FeCoB) or iron-boron (FeB) and can have a body-centered crystal structure.

The nonmagnet 37 has a function of suppressing an increase in the damping constant of the ferromagnet 36 and reducing the write current. The nonmagnet 37 contains, for example, at least one nitride or oxide selected from the group consisting of magnesium oxide (MgO), magnesium nitride (MgN), zirconium nitride (ZrN), niobium nitride (NbN), silicon nitride (SiN), aluminum nitride (AlN), hafnium nitride (HfN), tantalum nitride (TaN), tungsten nitride (WN), chromium nitride (CrN), molybdenum nitride (MoN), titanium nitride (TiN), and vanadium nitride (VN). In addition, the nonmagnet 37 may be a mixture of these nitrides or oxides. That is, the nonmagnet 37 can contain a ternary compound composed of three types of elements, for example, titanium aluminum nitride (AlTiN), as well as a binary compound composed of two types of elements.

The nonmagnet 38 is a nonmagnetic conductor and has a function as a top electrode that improves the electrical coupling characteristics between the upper end of the magnetoresistive effect element MTJ and the bit line BL. The nonmagnet 38 contains a high-melting-point metal. The high-melting-point metal is, for example, a material having a higher melting point than iron (Fe) and cobalt (Co) and includes at least one element selected from the group consisting of zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

In this embodiment, a write current is made to flow in the magnetoresistive effect element MTJ. This write current injects spin torque into the storage layer SL. The embodiment adopts a spin injection write scheme of controlling the magnetization direction of the storage layer SL based on injected spin torque. The magnetoresistive effect element MTJ can assume either a low resistance state or a high resistance state depending on whether the relative relationship between the magnetization directions of the storage layer SL and the reference layer RL is parallel or anti-parallel.

If a write current Ic0 having a certain magnitude is made to flow in the magnetoresistive effect element MTJ in the direction of an arrow A1 in FIG. 4, that is, a direction from the storage layer SL to the reference layer RL, the relative relationship between the magnetization directions of the storage layer SL and the reference layer RL becomes parallel. In this parallel state, the resistance value of the magnetoresistive effect element MTJ becomes lowest, and the magnetoresistive effect element MTJ is set in a low resistance state. This low resistance state is called a “P (Parallel) state” and is defined as, for example, a data “0” state.

If a write current Ic1 larger than the write current Ic0 is made to flow in the magnetoresistive effect element MTJ in the direction of an arrow A2 in FIG. 4, that is, a direction from the reference layer RL to the storage layer SL, the relative relationship between the magnetization directions of the storage layer SL and the reference layer RL becomes anti-parallel. In this anti-parallel state, the resistance value of the magnetoresistive effect element MTJ becomes highest, and the magnetoresistive effect element MTJ is set in a high resistance state. This high resistance state is called an “AP (Anti-Parallel) state” and is defined as, for example, a data “1” state.

Although the following description will be made according to the above data defining method, the manner of defining data “1” and data “0” is not limited to the above example. For example, a P state may be defined as data “1”, and an AP state may be defined as data “0”.

### 1.5 Configuration of Selector

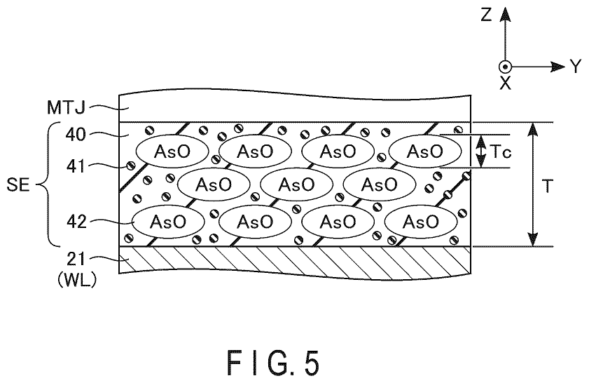

An example of a configuration of the selector SE will be described next with reference to FIG. 5. FIG. 5 is a cross-sectional view showing an example of a configuration of the selector SE.

As shown in FIG. 5, the selector SE includes an insulator 40, an additive 41, and a plurality of clusters 42.

The insulator 40 is a base material forming the selector SE. For example, the insulator 40 includes silicon oxide (SiO). The upper surface of the insulator 40 is in contact with the magnetoresistive effect element MTJ. The lower surface of the insulator 40 is in contact with the word line WL (the interconnect layer 21). Note that the selector SE may include an electrode provided on an interface in contact with the magnetoresistive effect element MTJ or an interface in contact with the word line WL (the interconnect layer 21).

The additive 41 added to the insulator 40 is a non-solid soluble material with respect to As in cluster 42. The additive 41 includes at least one element selected from the group consisting of thallium (Tl) and boron (B) or oxides of these elements. In other words, the insulator 40 includes silicon (Si), oxygen (O), and at least one element selected from the group consisting of thallium (Tl), and boron (B). The additive 41 has a function of inhibiting the growth of the clusters 42 in the insulator 40. That is, in the insulator 40 added with the additive 41, the clusters 42 having relatively small sizes can be formed. For example, the additive 41 is added into the insulator 40 by physical vapor deposition (PVD) or ion implantation.

The plurality of clusters 42 are scattered about in the insulator 40 (the insulator 40 added with the additive 41). For example, the cluster 42 is an aggregate of arsenic (As) oxides (AsO). For example, the selector SE contains about 5 at % to 50 at % of arsenic (As). The adjacent clusters 42 are insulated from each other by the insulator 40. For example, a film thickness Tc (a height Tc in the Z direction) of the cluster 42 is less than ½ of a film thickness T (a height T in the Z direction) of the insulator 40. That is, in the Z direction, the two or more clusters 42 are provided separately from each other. For example, the clusters 42 are formed by implanting arsenic (As) into the insulator 40 and heat-treating the resultant structure.

The selector SE in this embodiment contains silicon (Si), oxygen (O), arsenic (As), and at least one element selected from the group consisting of thallium (Tl) and boron (B).

For example, the distributions of the additive 41 and the clusters 42 in the insulator 40 can be checked by using analysis such as TEM (Transmission Electron Microscope) -EELS (Electron Energy-Loss spectroscopy) or TEM-EDX (Energy Dispersive X-ray spectroscopy).

### 1.6 Conduction Path of Selector

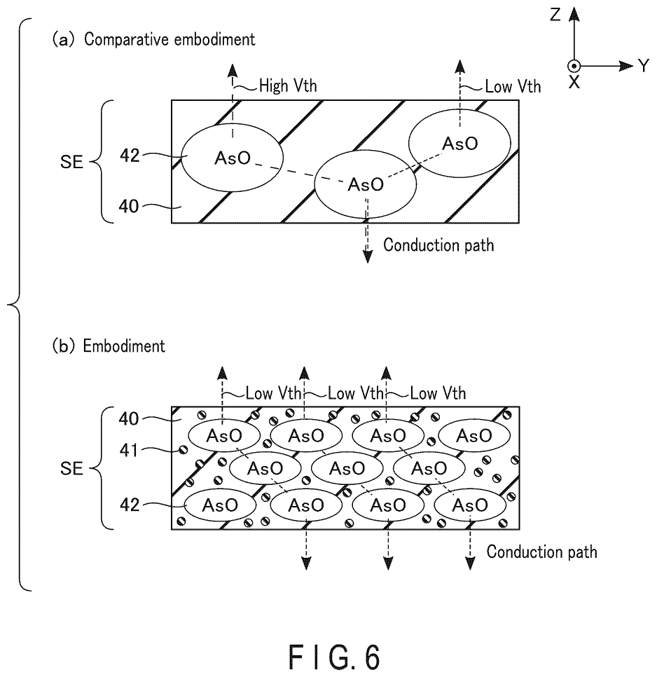

The conduction path of the selector SE will be described with reference to FIG. 6. FIG. 6 is a view showing (a) the conduction path of the selector SE with relatively large cluster sizes in a comparative embodiment and (b) the conduction path of the selector SE with relatively small cluster sizes in the embodiment.

For example, in order to stabilize the selector SE switch, a voltage with a certain magnitude (to be also referred to as a “forming voltage” hereinafter) needs to be applied first to the selector SE. This forms the conduction path of the selector SE. The conduction path is formed through the clusters 42. Once the forming voltage is applied to the selector SE, the selector SE can perform switching. The switching voltage (a threshold voltage Vth) of the selector SE after forming is lower than the forming voltage (Vf) and is given by Vf−Vth≥0(V). As the difference (Vf-Vth) increases, it is difficult to form a conduction path during forming, and hence the variation in the threshold voltage Vth increases. Accordingly, Vf−Vth<1(V) is preferable. At the time of forming, a voltage (V1) larger than the forming voltage (Vf) needs to be applied to a selected bit. If, however, the voltage V1 is excessively large, a non-selected bit is erroneously selected and hence a sufficient voltage is not applied to the selected bit. In a cross-point memory, the difference (Vf-Vth) is preferably minimized.

As indicated by (a) in FIG. 6, in a comparative embodiment, the insulator 40 does not contain the additive 41. For example, the cluster 42 has grown to ½ or more of the film thickness of the insulator 40. In a state in which the clusters 42 are relatively large, the distances between the clusters 42 in the conduction path vary depending on the placement of the clusters 42. In the case indicated by (a) in FIG. 6, the distance between the clusters 42 in the conduction path on the left side of the drawing sheet is larger than the distance between the clusters 42 in the conduction path on the right side of the drawing sheet. In this case, the threshold voltage Vth in the conduction path on the left side of the drawing sheet is higher than the threshold voltage Vth in the conduction path on the right side of the drawing sheet. The variation in the threshold voltage Vth tends to increase as the sizes of the clusters 42 increase in this manner. As a result, the bit-by-bit variation in the threshold voltage Vth of the selector SE becomes relatively large.

In contrast to this, as indicated by (b) in FIG. 6, in the embodiment, the sizes of the clusters 42 are suppressed to less than ½ of the film thickness of the insulator 40 added with the additive 41. The plurality of relatively small clusters 42 exist in the film thickness direction (Z direction) of the insulator 40. In the case indicated by (b) in FIG. 6, three conduction paths are formed. The variation in the distances between the clusters 42 in each conduction path is relatively small. Accordingly, the variation in the threshold voltage Vth due to each conduction path is smaller than that in the case indicated by (a) in FIG. 6. In addition, since the distances between the clusters 42 in each conduction path are relatively small, the thresholds Vth are relatively low. This reduces the difference between the forming voltage and the threshold voltage Vth and also reduces the bit-by-bit variation in the threshold voltage Vth of the selector SE.

### 1.7 Effects According to Embodiment

With the configuration according to this embodiment, the selector SE is allowed to add, as the additive 41 to the insulator 40, one element selected from the group consisting of thallium (Tl) and boron (B) or oxides of these elements. Adding the additive 41 can suppress the growth of the clusters 42 including arsenic oxide (AsO) in the insulator 40. That is, the relatively small clusters 42 can be formed. This makes it possible to suppress the bit-by-bit variation in the threshold voltage Vth of the selector SE. It is, therefore, possible to suppress operation errors in the selector SE and improve the reliability of the storage device 1.

### 2. Second Embodiment

The second embodiment will be described next. The second embodiment will exemplify the structure of a selector SE different from that according to the first embodiment. The structure will be described, focusing on differences from the first embodiment.

### 2.1 Configuration of Selector

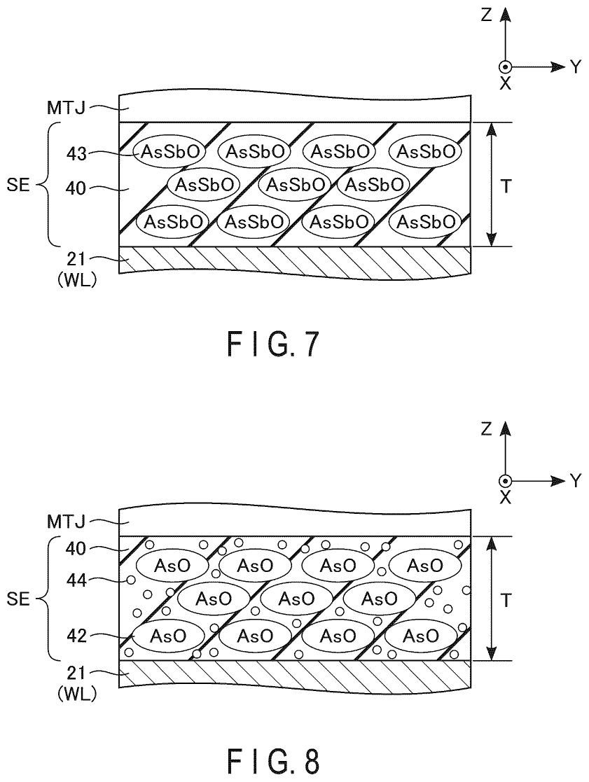

An example of a configuration of the selector SE will be described with reference to FIG. 7. FIG. 7 is a cross-sectional view showing an example of a configuration of the selector SE.

As shown in FIG. 7, the selector SE includes an insulator 40 and a plurality of clusters 43.

The insulator 40 is the same as in the first embodiment. The insulator 40 according to the second embodiment does not include the additive 41.

The plurality of clusters 43 are scattered about in the insulator 40. The cluster 43 according to this embodiment is an aggregate of ternary oxides (AsSbO) including arsenic (As) and antimony (Sb). For example, the concentration (the number of atoms) of antimony (Sb) in the cluster 43 is smaller than the concentration (the number of atoms) of arsenic (As). The adjacent clusters 43 are insulated from each other through the insulator 40. For example, the size of the cluster 43 is less than ½ of a film thickness T (a height T in the Z direction) of the insulator 40. That is, the two or more clusters 43 are provided separately from each other in the Z direction. For example, the cluster 43 is formed by implanting arsenic (As) and antimony (Sb) into the insulator 40 by ion implantation and heat-treating the resultant structure. Arsenic (As) and antimony (Sb) may be collectively or separately implanted. Note that the cluster 43 may be formed by forming an SiAsSbO film by PVD and heat-treating the resultant structure.

Antimony (Sb) has high affinity with arsenic (As) and high binding force. Accordingly, AsSbO can be easily formed. In addition, antimony (Sb) has a larger atomic radius than arsenic (As). For this reason, as compared with AsO, AsSbO is difficult to diffuse in the insulator 40. This inhibits the growth of the cluster 43.

The selector SE according to this embodiment contains silicon (Si), oxygen (O), arsenic (As), and antimony (Sb).

As in the first embodiment, for example, the distribution of the clusters 43 in the insulator 40 can be checked by using analysis such as TEM-EELS or TEM-EDX.

### 2.2 Effects according to Embodiment

With the configuration according to this embodiment, the selector SE is allowed to form the cluster 43 including oxide (AsSbO) including arsenic (As) and antimony (Sb) in the insulator 40. Forming AsSbO can suppress the growth of the clusters 43. That is, the relatively small clusters 43 can be formed. This makes it possible to suppress the bit-by-bit variation in the threshold voltage Vth of the selector SE. It is, therefore, possible to suppress operation errors in the selector SE and improve the reliability of a storage device 1.

### 3. Third Embodiment

The third embodiment will be described next. The third embodiment will exemplify the structure of a selector SE different from those according to the first and second embodiments. The structure will be described, focusing on differences from the first and second embodiments.

### 3.1 Configuration of Selector

An example of a configuration of the selector SE will be described with reference to FIG. 8. FIG. 8 is a cross-sectional view showing an example of a configuration of the selector SE.

As shown in FIG. 8, the selector SE includes an insulator 40 and a plurality of clusters 42.

The insulator 40 (silicon oxide (SiO)) according to this embodiment includes a plurality of oxygen defects 44 in the film. Note that the insulator 40 may include pinhole instead of oxygen defects 44 or both the oxygen defects 44 and pinholes. For example, the number of oxygen defects 44 is larger than the number of clusters 42. The oxygen defects 44 suppress the growth of the clusters 42 including AsO. For example, optimizing CVD deposition conditions (gas flow rate, deposition temperature, plasma power, and the like) makes it possible to adjust the concentration of the oxygen defects 44 in the insulator 40. The same applies to a case where the insulator 40 is formed by PVD.

The clusters 42 are the same as in the first embodiment.

For example, the oxygen defects 44 in the insulator 40 can be checked by using analysis such as TEM-EELS or TEM-EDX.

### 3.2 Effects according to Embodiment

With the configuration according to this embodiment, the selector SE is allowed to form the insulator 40 including the oxygen defects 44 (and/or pinholes). The oxygen defects 44 can suppress the growth of the clusters 42. That is, the relatively small clusters 42 can be formed. This makes it possible to suppress the bit-by-bit variation in the threshold voltage Vth of the selector SE. It is, therefore, possible to suppress operation errors in the selector SE and improve the reliability of a storage device 1.

### 4. Fourth Embodiment

The fourth embodiment will be described next. The fourth embodiment will exemplify the structure of a selector SE different from those according to the first to third embodiments. The structure will be described, focusing on differences from the first to third embodiments.

### 4.1 Configuration of Selector

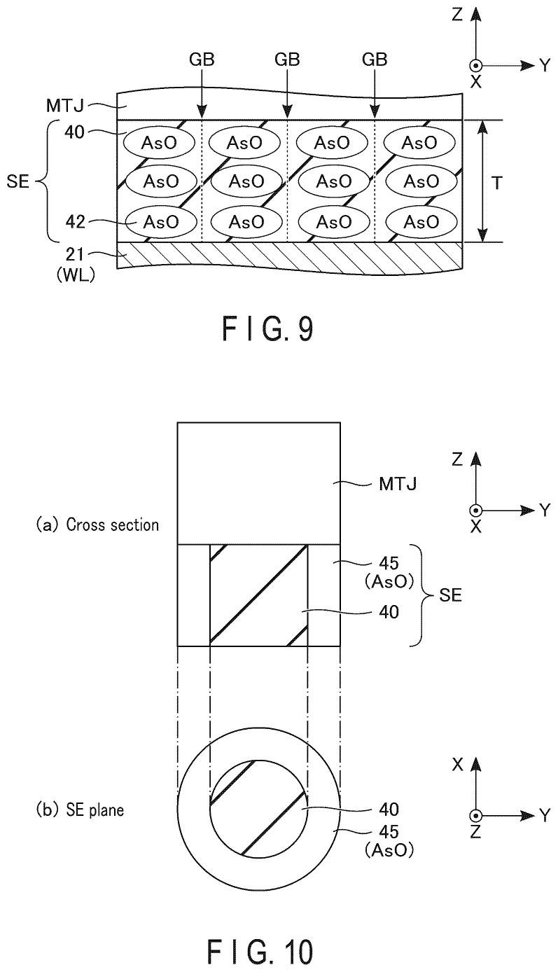

An example of a configuration of the selector SE will be described with reference to FIG. 9. FIG. 9 is a cross-sectional view showing an example of a configuration of the selector SE.

As shown in FIG. 9, the selector SE includes an insulator 40 and a plurality of clusters 42.

The insulator 40 (silicon oxide (SiO)) according to this embodiment has a columnar crystal structure. That is, the insulator 40 includes a plurality of grain boundaries GB extending in the Z direction. Note that the insulator 40 may have a crystal structure other than the columnar crystal structure. The grain boundaries GB suppress the growth of the clusters 42 including AsO. The columnar crystal structure can be formed by polycrystallizing the word line WL (the interconnect layer 21). The columnar crystallization of the insulator 40 may be promoted by inserting a polycrystalline electrode between the insulator 40 and the word line WL (the interconnect layer 21).

The clusters 42 are the same as in the first embodiment.

For example, the crystal structure of the insulator 40 can be checked by using analysis such as In-plane X-ray diffraction or the like.

### 4.2 Effects according to Embodiment

With the configuration according to this embodiment, the selector SE is allowed to form the insulator 40 including the grain boundaries GB. The grain boundaries GB can suppress the growth of the clusters 42. That is, the relatively small clusters 42 can be formed. This makes it possible to suppress the bit-by-bit variation in a threshold voltage Vth of the selector SE. It is, therefore, possible to suppress operation errors in the selector SE and improve the reliability of a storage device 1. The grain size of the insulator 40 in an XY plane is preferably less than ½ of a film thickness T (a height T in the Z direction) of the insulator 40.

### 5. Fifth Embodiment

The fifth embodiment will be described next. The fifth embodiment will exemplify the structure of a selector SE different from those according to the first to fourth embodiments. The structure will be described, focusing on differences from the first to fourth embodiments. 5.1 Configuration of Selector

An example of a configuration of the selector SE will be described with reference to FIG. 10. FIG. 10 is a view showing an example of a cross-sectional view and a plan view of the selector SE.

As indicated by (a) in FIG. 10, the selector SE according to this embodiment includes an insulator 40 and a member 45.

The insulator 40 is the same as in the first embodiment. Note that the insulator 40 according to the fifth embodiment does not include the additive 41.

The member 45 is provided so as to surround a side surface of the insulator 40. The upper surface of the member 45 is in contact with a magnetoresistive effect element MTJ. The lower surface of the member 45 is in contact with the word line WL (the interconnect layer 21). The member 45 contains an arsenic (As) oxide (AsO). A conduction path of the selector SE is formed in the member 45. For example, the member 45 is formed by implanting arsenic (As) into the side surface of the insulator 40 by oblique ion implantation and then heat-treating the resultant structure.

For example, the insulator 40 and the member 45 can be checked by using analysis such as TEM-EELS or TEM-EDX.

### 5.2 Effects according to Embodiment

With the configuration according to this embodiment, the selector SE is allowed to form the member 45 containing arsenic (As) oxide (AsO) on the side surface of the insulator 40. This makes it possible to suppress the bit-by-bit variation in a threshold voltage Vth of the selector SE. It is, therefore, possible to suppress operation errors in the selector SE and improve the reliability of a storage device 1.

### 6. Modifications

Note that, in addition to the above embodiments, various modifications can be applied to the present invention. For example, the first to fifth embodiments can be combined as long as it is possible. The third to fifth embodiments may be combined with the second embodiment so as to allow the use of AsSbO instead of AsO. In addition, the first embodiment and the third embodiment may be combined so as to allow the insulator 40 to include the additive 41 and the oxygen defects 44.

In addition, “coupling” between constituent elements in the above embodiments includes a state in which, for example, they are indirectly coupled to each other through other elements such as transistors or resistors.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a first interconnect extending in a first direction;
a switching element provided on the first interconnect and containing silicon (Si), oxygen (O), arsenic (As), and at least one element selected from the group consisting of thallium (Tl) and boron (B);
a variable resistance element provided on the switching element; and
a second interconnect extending in a second direction intersecting the first direction and provided on the variable resistance element.

2. The device according to claim 1, wherein the switching element includes:
an insulator containing silicon oxide (SiO) and at least one element selected from the group consisting of thallium (Tl) and boron (B); and
a plurality of clusters provided in the insulator and each containing arsenic oxide (AsO).

3. The device according to claim 2, wherein each of the plurality of clusters has a size less than ½ of a film thickness of the switching element.

4. The device according to claim 1, wherein the switching element is a two-terminal switching element.

5. The device according to claim 1, wherein the variable resistance element is a magnetoresistive effect element.

6. The device according to claim 5, wherein the variable resistance element includes:
a first ferromagnet;
a second ferromagnet;
a third ferromagnet;
a first nonmagnet provided between the switching element and the first ferromagnet;
a second nonmagnet provided between the first ferromagnet and the second ferromagnet;
a third nonmagnet provided between the second ferromagnet and the third ferromagnet; and
a fourth nonmagnet provided between the third ferromagnet and the second interconnect.

7. The device according to claim 6, wherein the first ferromagnet is a shift cancel layer,
the second ferromagnet is a reference layer, and
the third ferromagnet is a storage layer.

8. The device according to claim 6, wherein the variable resistance element has a first resistance value in a case where a magnetization direction of the second ferromagnet and a magnetization direction of the third ferromagnet are in a parallel state and
the variable resistance element has a second resistance value in a case where the magnetization direction of the second ferromagnet and the magnetization direction of the third ferromagnet are in an anti-parallel state.

9. A storage device comprising:
a first interconnect extending in a first direction;
a switching element provided on the first interconnect and containing silicon (Si), oxygen (O), arsenic (As), and antimony (Sb);
a variable resistance element provided on the switching element; and
a second interconnect extending in a second direction intersecting the first direction and provided on the variable resistance element.

10. The device according to claim 9, wherein the switching element includes:
an insulator containing silicon oxide (SiO); and
a plurality of clusters provided in the insulator and each containing oxide containing arsenic (As) and antimony (Sb).

11. The device according to claim 10, wherein each of the plurality of clusters has a size less than ½ of a film thickness of the switching element.

12. The device according to claim 9, wherein the switching element is a two-terminal switching element.

13. The device according to claim 9, wherein the variable resistance element is a magnetoresistive effect element.

14. A storage device comprising:
a first interconnect extending in a first direction;
a switching element provided on the first interconnect and including an insulator and a plurality of clusters provided in the insulator, the insulator containing silicon oxide (SiO) that includes at least one of an oxygen defect, a pinhole, and a grain boundary, each of the plurality of clusters containing arsenic oxide (AsO);
a variable resistance element provided on the switching element; and
a second interconnect extending in a second direction intersecting the first direction and provided on the variable resistance element.

15. The device according to claim 14, wherein each of the plurality of clusters has a size less than ½ of a film thickness of the switching element.

16. The device according to claim 14, wherein the switching element is a two-terminal switching element.

17. The device according to claim 14, wherein the variable resistance element is a magnetoresistive effect element.

18. A storage device comprising:
a first interconnect extending in a first direction;
a switching element provided on the first interconnect and including an insulator and a member provided so as to surround a side surface of the insulator, the insulator containing silicon (Si) and oxygen (O), the member containing arsenic oxide (AsO);
a variable resistance element provided on the switching element; and
a second interconnect extending in a second direction intersecting the first direction and provided on the variable resistance element.

19. The device according to claim 18, wherein the switching element is a two-terminal switching element.

20. The device according to claim 18, wherein the variable resistance element is a magnetoresistive effect element.
